(19) United States
(12) Patent Application Publication
(10) Pub. No.: US 2026/0219590 A1
(43) Pub. Date: Jul. 30, 2026

(54) CONTROL CONDUCTIVITY OF POLYIMIDE FILM BY IRRADIATION FOR RTC APPLICATION

(71) Applicant: ASML NETHERLANDS B.V., Veldhoven (NL)

(72) Inventors: Jungseung KIM, Trumbull, CT (US); Earl William EBERT, Oxford, CT (US)

(73) Assignee: ASML NETHERLANDS B.V., Veldhoven (NL)

(21) Appl. No.: 19/145,191

(22) PCT Filed: Dec. 19, 2023
(86) PCT No.: PCT/EP2023/086770

§ 371 Date: Jul. 1, 2025

Related U.S. Application Data
(60) Provisional application No. 63/439,310, filed on Jan. 17, 2023.

(51) Int. Cl. G03F 7/00

(52) U.S. Cl. CPC G03F 7/70925; G03F 7/70708

(57) ABSTRACT

A cleaning apparatus for cleaning a reticle stage of a lithographic apparatus. The apparatus includes a substrate having a frontside and a backside opposite the frontside. A polyimide layer is disposed on the frontside of the substrate and is configured to contact the reticle stage to remove particles on the reticle stage. The polyimide layer includes radicals therein to provide the polyimide layer with a conductivity for dissipating charge on the reticle stage.

### CROSS-REFERENCE TO RELATED APPLICATION

This application claims priority of U.S. application 63/439,310 which was filed on 17 Jan. 2023 and which is incorporated herein in its entirety by reference.

### TECHNICAL FIELD

The present disclosure relates to reticle table cleaning (RTC) apparatuses, systems, and methods, for example, charge dissipative and particle removing RTC apparatuses for lithographic apparatuses and systems.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, deep ultraviolet (DUV) radiation with a wavelength of 157 nm or 193 nm or 248 nm.

A reticle stage used in a lithographic apparatus to hold a patterning device can become contaminated over time (e.g., accumulate particles). The contamination can be transferred from the reticle stage to the patterning device, for example, by an electrostatic clamp that holds the patterning device during patterning. The contamination can accumulate on the patterning device and cause patterning errors and/or defects. A contaminated reticle stage can be manually cleaned, but manual cleaning can leave a residue of fine particles. Further, manual cleaning requires the lithographic apparatus be vented to atmospheric pressure and partially disassembled, reducing overall yield.

Current RTC devices use an insulating top coating that can accumulate charge over multiple cycles (e.g., trapping of charge carriers in insulating coating). Under vacuum, RTC devices can eventually stick to the reticle stage due to parasitic charge between opposing insulating contact surfaces. Parasitic charge requires that the lithographic apparatus be vented to atmospheric pressure and partially dissembled in order to manually separate the RTC device from the reticle stage. One way to dissipate charge between the reticle stage (e.g., the electrostatic clamp) and an RTC device is to use a separate conductive device disposed between each load of the RTC device. However, this process slows scanning ability and overall efficiency of the lithographic apparatus since two devices are needed.

A conductive frontside layer has been proposed to mitigate and/or remove the sticking problem between the clamp 204 and the frontside layer 410. In a prior solution in PCT Patent Publication WO 2022/128750, hereby incorporated by reference in its entirety, it has been proposed to achieve this by doping the frontside layer by using various fillers and/or additives.

### BRIEF SUMMARY

There is a desire to dissipate charge on the reticle stage, remove particles from the reticle stage, and improve efficiency and overall yield in the lithographic apparatus with an efficient and cost-effective conductive RTC device.

In one embodiment, the present disclosure comprises a cleaning apparatus for cleaning a reticle stage of a lithographic apparatus. The apparatus comprises a substrate having a frontside and a backside opposite the frontside, and a polyimide layer disposed on the frontside of the substrate. The polyimide layer is configured to contact the reticle stage to remove particles on the reticle stage and has radicals therein to provide the polyimide with a conductivity for dissipating charge on the reticle stage.

In some embodiments, the radicals are formed at least in part from a broken C—N bond in the imide group of the polyimide layer and/or from a broken C—O bond of the polyimide proton. Radicals are formed upon radiation on the chemical bonds of C—N, C—O, phenyl rings of the imide backbone structure.

In some embodiments, the polyimide layer has stiffness lower than that of the substrate, and a thickness no greater than 8 microns in order to generate an electrostatic field between the polyimide layer and the reticle stage.

In some embodiments, a chromium nitride layer disposed between the polyimide layer and the substrate. The CrN layer, which has much higher conductivity, e.g., between ~100 S/cm to ~300 S/cm (e.g., ~200 S/cm) than the polyimide layer can serve to facilitate the discharge process by creating a charge gradient from the irradiated polyimide layer. The conductive CrN layer can also be used for the purpose of clamping the reticle.

In some embodiments, a positioner is coupled to the backside of the substrate and configured to translate the polyimide layer relative to the reticle stage.

In accordance with another embodiment, a lithographic apparatus is provided that includes the cleaning apparatus. Specifically, the lithographic apparatus comprises an illumination system configured to illuminate a patterning device, a projection system configured to project an image of the patterning device onto a patterning substrate, and a reticle stage configured to support the patterning device and comprising a chuck and an electrostatic clamp comprising a plurality of burls. The cleaning apparatus is configured for cleaning the reticle stage, the apparatus and comprises a substrate having a frontside and a backside opposite the frontside, a polyimide layer disposed on the frontside of the substrate and configured to contact the reticle stage to dissipate charge on the reticle stage and to remove particles on the reticle stage. the polyimide layer has radicals therein to provide the polyimide with a conductivity for dissipating charge on the reticle stage.

In another embodiment, method of forming a reticle stage cleaning apparatus for removing particles on a reticle stage in a lithographic apparatus is provided. The method comprises providing a substrate having a frontside and a backside opposite the frontside; disposing a polyimide layer on the frontside of the substrate; and irradiating the polyimide layer with radiation to increase a conductivity of the polyimide layer.

In one embodiment, the irradiation of the polyimide layer forms radicals in the polyimide layer to increase the conductivity of the polyimide layer.

In one embodiment, the irradiating comprises using one or more of an electron beam, gamma radiation, ultraviolet photons, laser radiation, or microwaves.

In one embodiment, the radicals are formed from vacuum and from atmospheric conditions.

Further features and exemplary aspects of the embodiments, as well as the structure and operation of various embodiments, are described in detail below with reference to the accompanying drawings. It is noted that the embodiments are not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the embodiments and, together with the description, further serve to explain the principles of the embodiments and to enable a person skilled in the relevant art(s) to make and use the embodiments.

FIG. 1 is a schematic illustration of a lithographic apparatus, according to an exemplary embodiment.

FIG. 2 is a schematic perspective illustration of a reticle stage and a reticle, according to an exemplary embodiment.

FIG. 3 is a schematic cross-sectional illustration of the reticle stage and the reticle shown in FIG. 2.

FIG. 4 is a schematic perspective illustration of a RTC reticle, according to an exemplary embodiment.

FIG. 5 is a schematic cross-sectional illustration of the RTC reticle shown in FIG. 4.

FIGS. 6A-6C illustrate a process cycle to remove particles from a reticle stage to a RTC reticle, according to an exemplary embodiment.

FIG. 7 is a schematic perspective illustration of a RTC reticle, according to an exemplary embodiment.

FIG. 8 is a schematic cross-sectional illustration of the RTC reticle shown in FIG. 7.

FIG. 9 is a schematic perspective illustration of a reticle stage and a RTC reticle, according to an exemplary embodiment.

FIG. 10 is a schematic cross-sectional illustration of the reticle stage and the RTC reticle shown in FIG. 9.

FIG. 11 illustrates a manufacturing flow diagram for manufacturing a RTC reticle, according to an exemplary embodiment.

FIG. 12 illustrates a cleaning flow diagram for removing particles from a reticle stage to a RTC reticle, according to an exemplary embodiment.

The features and exemplary aspects of the embodiments will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this present invention. The disclosed embodiment(s) merely exemplify the present invention. The scope of the invention is not limited to the disclosed embodiment(s). The present invention is defined by the claims appended hereto.

The embodiment(s) described, and references in the specification to “one embodiment,” “an embodiment,” “an example embodiment,” “an exemplary embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., 1%, 2%, 5%, 10%, or ±15% of the value).

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure may be implemented.

### Exemplary Lithographic System

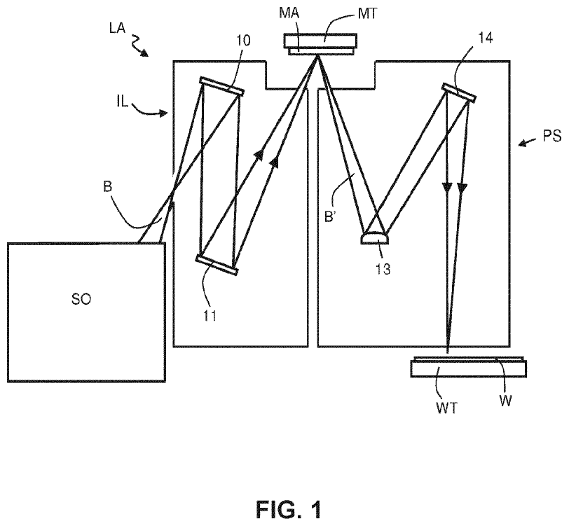

FIG. 1 shows a lithographic system comprising a radiation source SO and a lithographic apparatus LA. The radiation source SO is configured to generate an EUV and/or a DUV radiation beam B and to supply the EUV and/or DUV radiation beam B to the lithographic apparatus LA. The lithographic apparatus LA comprises an illumination system IL, a support structure MT (e.g., a mask table, a reticle table, a reticle stage) configured to support a patterning device MA (e.g., a mask, a reticle), a projection system PS, and a substrate table WT configured to support a substrate W.

The illumination system IL is configured to condition the EUV and/or DUV radiation beam B before the EUV and/or DUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV and/or DUV radiation beam B with a desired cross-sectional shape and a desired intensity distribution. The illumination system IL may include other mirrors or devices in addition to, or instead of, the faceted field min-or device 10 and faceted pupil mirror device 11.

After being thus conditioned, the EUV and/or DUV radiation beam B interacts with the patterning device MA. This interaction may be reflective (as shown), which may be preferred for EUV radiation. This interaction may be transmissive, which may be preferred for DUV radiation. As a result of this interaction, a patterned EUV and/or DUV radiation beam B′ is generated. The projection system PS is configured to project the patterned EUV and/or DUV radiation beam B′ onto the substrate W. For that purpose, the projection system PS may comprise a plurality of minors 13, 14 which are configured to project the patterned EUV and/or DUV radiation beam B′ onto the substrate W held by the substrate table WT. The projection system PS may apply a reduction factor to the patterned EUV and/or DUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV and/or DUV radiation beam B′, with a pattern previously formed on the substrate W.

### Exemplary Reticle Stage Apparatus and Reticle Apparatus

As discussed above, a reticle stage (e.g., support structure MT) used in a lithographic apparatus (e.g., lithographic apparatus LA) to hold a patterning device (e.g., patterning device MA) can become contaminated over time (e.g., accumulate particles). The contamination can be transferred from the reticle stage to the patterning device, for example, by an electrostatic clamp that holds the patterning device during patterning.

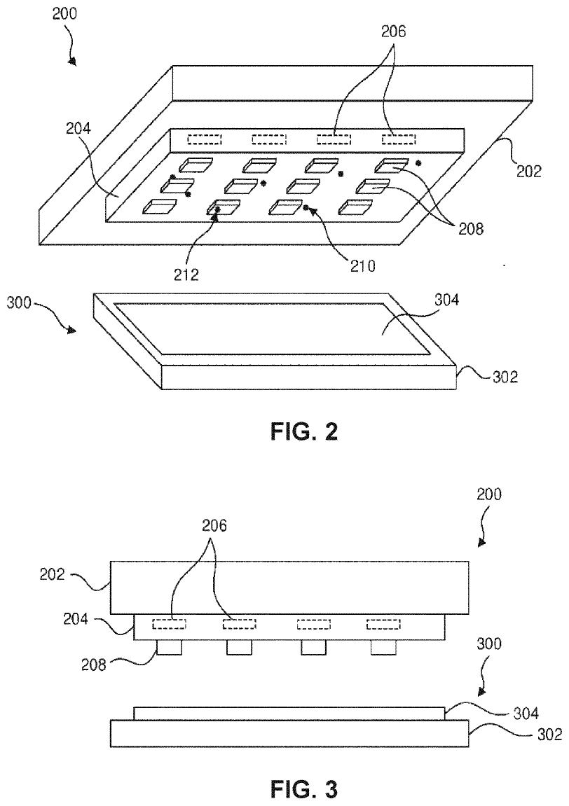

FIGS. 2 and 3 illustrate reticle stage 200 and reticle 300, according to various exemplary embodiments. FIG. 2 is a schematic illustration of reticle stage 200 and reticle 300, according to an exemplary embodiment. FIG. 3 is a schematic cross-sectional illustration of reticle stage 200 and reticle 300 shown in FIG. 2.

FIGS. 2 and 3 illustrate reticle stage 200, according to various exemplary embodiments.

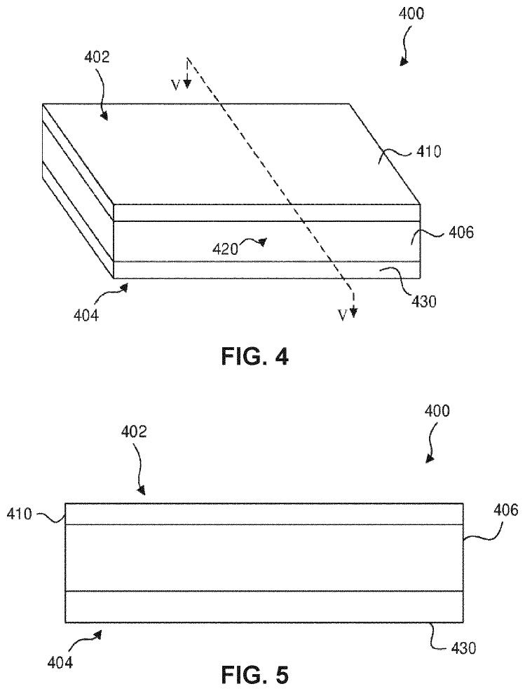

Reticle stage 200 can be configured to support a patterning device (e.g., reticle 300). Reticle stage 200 can be further configured to support a cleaning apparatus (e.g., RTC reticles 400,400′, 400″, 400′″, 400″″, 400′″″, 400″″″ shown in FIGS. 4-14). Although reticle stage 200 is shown in FIGS. 2 and 3 as a stand-alone apparatus and/or system, the embodiments of this disclosure can be used with other apparatuses and/or systems, such as, but not limited to, lithographic apparatus LA. support structure MT, patterning device MA, reticle 300, and/or RTC reticles 400,400′, 400″, 400′″, 400″″, 400, 400″″″.

As shown in FIGS. 2 and 3, reticle stage 200 can include clamp chuck 202 and electrostatic clamp 204. Clamp chuck 202 can be configured to support electrostatic clamp 204 (e.g., by negative pressure). Electrostatic clamp 204 can be configured to support a patterning device (e.g., reticle 300) and/or a cleaning apparatus (e.g., RTC reticles 400, 400′, 400″, 400′″, 400″″, 400′″″, 400″″″) electrostatically. For example, a voltage can be applied to electrostatic clamp 204 to generate an electrostatic field between an object (e.g., reticle 300, RTC reticles 400, 400′, 400″, 400′″, 400″″, 400′″″, 400″″″) and electrostatic clamp 204 to hold the object.

As shown in FIGS. 2 and 3, electrostatic clamp 204 can include clamp electrodes 206 (e.g., embedded) and burls 208 (e.g., exterior projections or bumps). In some embodiments, clamp electrodes 206 can be embedded in electrostatic clamp 204 and aligned (e.g., vertically) with burls 208. Clamp electrodes 206 can be configured to generate an electrostatic field between burls 208 and/or an object (e.g., reticle 300, RTC reticles 400,400′, 400″, 400′″, 400″″, 400′″″, 400′″ ′″). Burls 208 can be configured to physically contact an object (e.g., reticle 300, RTC reticles 400,400′, 400″, 400′″, 400″″, 400′″″, 400″″″) in order to clamp (e.g., electrostatically) and hold the object.

In some embodiments, as shown in FIG. 2, electrostatic clamp 204 can include various particles or contaminants on an exterior surface (e.g., contacting surface). for example, first particle 210 can be disposed between burls 208 and second particle 212 can be disposed on burls 208. Contaminants (e.g., first particle 210, second particle 212) can accumulate on electrostatic clamp 204 and cause patterning errors and/or defects. For example, contaminants (e.g., first particle 210, second particle 212) can be transferred to an object (e.g., reticle 300, RTC reticles 400, 400′, 400″, 400′″, 400″″, 400′″″, 400′″ ′″) during electrostatic clamping of the object.

In some embodiments, electrostatic clamp 204 can be configured to provide a voltage on an object (e.g., reticle 300, RTC reticles 400, 400′, 400″, 400′″, 400″″, 400′″″, 400″″″) relative to reticle stage 200 (e.g., burls 208 of electrostatic clamp 204). For example, clamp electrodes 206 can provide a voltage difference 11V (e.g., from an applied negative voltage (−Y) or positive voltage (+Y)) between reticle stage 200 and the object such that an electrostatic field is generated between reticle stage 200 and the object. The generated electrostatic field creates an electrostatic force (e.g., Lorentz force) and/or a Van der Waals force on contaminants (e.g., first particle 210, second particle 212, etc.) and causes the contaminants to move from reticle stage 200 (e.g., electrostatic clamp 204) to the object.

FIGS. 2 and 3 illustrate reticle 300, according to various exemplary embodiments. Reticle 300 can be configured to generate a patterned radiation beam (e.g., patterned EUV and/or DUV radiation beam B′). Although reticle 300 is shown in FIGS. 2 and 3 as a stand-alone apparatus and/or system, the embodiments of this disclosure can be used with other apparatuses and/or systems, such as, but not limited to, lithographic apparatus LA, support structure MT, reticle stage 200, and/or patterning device MA.

As shown in FIGS. 2 and 3, reticle 300 can include patterning device 302 (e.g., patterning device MA) and backside layer 304. Backside layer 304 can be configured to contact burls 208 of electrostatic clamp 204 so that reticle stage 200 can hold (e.g., electrostatically) reticle 300 without damaging patterning device 302. Backside layer 304 can be disposed on a backside of patterning device 302. In some embodiments, backside layer 304 can include a polymer or a combination of polymers. For example, backside layer 304 can include polyimide, Viton®, polytetrafluoroethylene (PTFE), Teflon, fluoropolymers, and/or any other material with a stiffness lower than that of patterning device 302.

Contaminants (e.g., first particle 210, second particle 212) on electrostatic clamp 204 and/or reticle 300 can cause damage to electrostatic clamp 204, damage to reticle 300, and/or patterning errors (e.g., overlay misalignment or voids).

### Exemplary Reticle Table Cleaning (RTC) Reticle Apparatus

As discussed above, contaminants (e.g., first particle 210, second particle 212, etc.) can accumulate on a patterning device (e.g., reticle 300) and/or a patterning device support (e.g., reticle stage 200) and cause patterning errors and/or defects. A contaminated reticle stage (e.g., reticle stage 200) can be manually cleaned, but manual cleaning can leave a residue of fine particles, producing new contaminants. Further, manual cleaning requires the lithographic apparatus (e.g., lithographic apparatus LA) be vented to atmospheric pressure and partially disassembled, reducing overall yield.

Certain existing RTC devices use an insulating top coating that can accumulate charge over multiple cycles (e.g., trapping of charge carriers in insulating coating). Under vacuum, RTC devices can eventually stick to the reticle stage due to parasitic charge between opposing insulating contact surfaces. Parasitic charge requires that the lithographic apparatus be vented to atmospheric pressure and partially dissembled in order to manually separate the RTC device from the reticle stage. One way to dissipate charge between the reticle stage (e.g., the electrostatic clamp) and an RTC device is to use a separate conductive device disposed between each load of the RTC device. However, this process has the potential to slow scanning ability and overall efficiency of the lithographic apparatus since two devices are needed.

Embodiments of RTC reticle apparatuses, systems, and methods as discussed below may dissipate charge on the reticle stage, remove particles from the reticle stage, and improve efficiency, scanning ability, and overall yield in the lithographic apparatus.

FIGS. 4 and 5 illustrate RTC reticle 400, according to various exemplary embodiments. FIG. 4 is a schematic perspective illustration of RTC reticle 400, according to an exemplary embodiment. FIG. 5 is a schematic cross-sectional illustration of RTC reticle 400 shown in FIG. 4 (along the plane indicated by V-V in FIG. 4). RTC reticle 400 can be configured to clean reticle stage 200 in a lithographic apparatus (e.g., lithographic apparatus LA). RTC reticle 400 can be further configured to dissipate charge accumulated on reticle stage 200 (e.g., accumulated charge on electrostatic clamp 204). RTC reticle 400 can be further configured to remove contaminants (e.g., first particle 210, second particle 212, etc.) on reticle stage 200 (e.g., electrostatic clamp 204) via an electrostatic field generated between RTC reticle 400 and reticle stage 200. Although RTC reticle 400 is shown in FIGS. 4 and 5 as a stand-alone apparatus and/or system, the embodiments of this disclosure can be used with other apparatuses and/or systems, such as, but not limited to, lithographic apparatus LA, support structure MT, reticle stage 200, patterning device MA, and/or reticle 300.

As shown in FIGS. 4 and 5, RTC reticle 400 can include frontside 402, backside 404, substrate 406, first frontside layer 410, and/or positioner 430. RTC reticle 400 has frontside 402 and backside 404 opposite frontside 402. Frontside 402 is configured to contact reticle stage 200. For example, frontside 402 can contact burls 208 of electrostatic clamp 204. In some embodiments, substrate 406 can be disposed between first frontside layer 410 and positioner 430. In some embodiments, substrate 406 can be an insulator. For example, substrate 406 can be fused silica, quartz, silicon oxide, silicon, a glass, a ceramic, a semiconductor, and/or some combination thereof.

First frontside layer 410 can be configured to contact reticle stage 200 (e.g., burls 208 of electrostatic clamp 204) to dissipate charge accumulated on reticle stage 200. First frontside layer 410 can be further configured to contact reticle stage 200 (e.g., burls 208 of electrostatic clamp 204) to remove contaminants (e.g., first particle 210, second particle 212, etc.). First frontside layer 410 can be disposed on a frontside of substrate 406 (e.g., frontside 402). In some embodiments, first frontside layer 410 can be conductive. In one embodiment, a more conductive frontside layer 410 is provided to mitigate and/or remove the sticking problem between the clamp 204 and the frontside layer 410. It is also desirable to maintain controlled thickness of the frontside layer, for example, no greater than about 8 μm in order to Achieve the desired clamping operation (e.g., in order to generate an electrostatic field between first frontside layer 410 and reticle stage 200).

In prior solutions, such as in PCT Patent Publication WO 2022/128750, it has been proposed to achieve this by doping the frontside layer by using various fillers and/or additives. In one embodiment of the present disclosure, the frontside layer 410 is a conductive polyimide layer. While polyimide is typically an insulator, the conductivity of the polyamide layer 410 is controlled (increased) by irradiating the polyamide material. For example, irradiation of the polyamide layer 410 can be performed by electron beam, gamma radiation, ultraviolet photons, laser radiation, or any combination thereof to modulate the degree of conductivity of the polyimide layer (or frontside layer) 410.

Prior to irradiation, the virgin polyimide would have a typical conductivity of approximately 10\hat{ }−18 S/cm (i.e., unit, Siemen/cm=1/(ohm*cm). In accordance with one embodiment, with application of sufficient dosing of radiation, the conductivity of the polyimide is increased to a minimum of 10\hat{ }−11 [S/cm]. In another embodiment, the conductivity of the polyimide is increased to at least 10\hat{ }−3 [S/cm].

Various scientific journals have established the ability to change the conductivity of polyimide materials. For example, see Review of Radiation-Induced Effects in Polyimide, Appl. Sci. 2019, 9, 1999; doi:10.3390/app9101999, hereby incorporated by reference in its entirety. In one embodiment, the polyimide layer is irradiated with 90 keV protons.

In one embodiment, the irradiation of polyimide causes the bond breakage of the carbonyl (C═O), aromatic ether (C—O—C) moieties and a ring opening reaction of cyclic imide (C—N). Exposure of polyimide to UV irradiation results in the formation of a high concentration of radicals that originate from a broken C—N bond in the imide group and the C—O bond of the ether of polyimide. Radicals are formed from radiation-induced chemical bonds such as modified C—N, modified C—O bond, modified phenyl rings on the imide backbone structure.

In one embodiment, the UV generated radicals are situated near the surface of the polyimide layer, e.g., within ~500 nm depth of the surface. In one embodiment, DUV radiation is used to irradiate the polyimide layer. In one embodiment the DUV beam B discussed above can be directed or funneled during an RTC irradiation process to irradiate the frontside polyimide layer 410 to generate radicles therein.

In some embodiments, first frontside polyimide layer 410 has a stiffness that is lower than a stiffness of substrate 406. For example, first frontside layer 410 can have a stiffness of 50 N/m and substrate 406 can have a stiffness of 1800 N/m. In some embodiments, first frontside layer 410 can be substantially planar. For example, as shown in FIGS. 4 and 5, first frontside layer 410 can be planar (e.g., uniform thickness).

In some embodiments, first frontside layer 410 has a thickness no greater than about 8 microns in order to generate an electrostatic field between first frontside layer 410 and reticle stage 200.

In some embodiments, the first frontside layer 410 acts as a leaky capacitor that can dissipate charge in 1 second or less. In addition, both the layer 410 and the layer 406 together can act as a leaky capacity. Layer 406 can also facilitate the discharge process to improve overall RTC process efficiency.

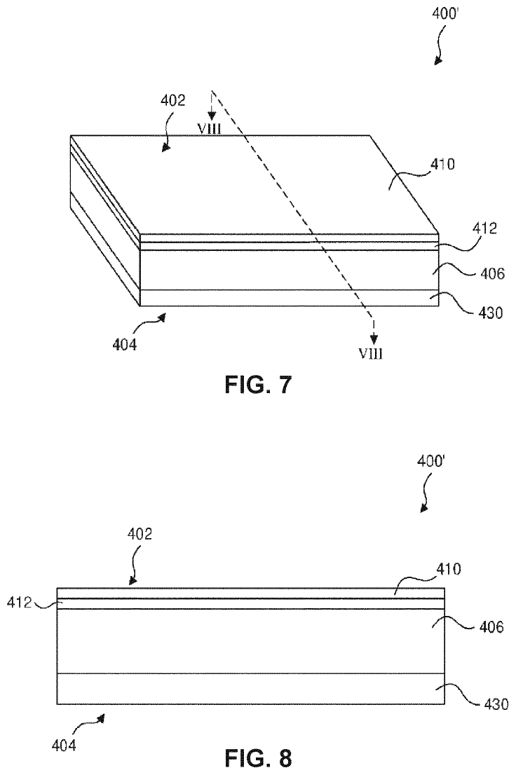

In some embodiments, RTC reticle 400 can optionally include second frontside layer 412 disposed between first frontside layer 410 and substrate 406. For example, as shown in FIGS. 7 and 8, second frontside layer 412 can be insulating (e.g., an insulating polymer) and disposed below first frontside layer 410 (e.g., a conductive metal and/or a conductive polymer). As will be appreciated, in some embodiments, the first frontside layer 410 can act as a passive conductor (e.g., first frontside layer 410 can be grounded or maintained at 0 V). For example, clamp electrodes 206 of electrostatic clamp 204 can provide a voltage on burls 208 relative to first frontside layer 410 to generate an electrostatic field between electrostatic clamp 204 and first frontside layer 410. In one embodiment, the two frontside layers 410 and 412 may act as “hierarchical layers” to provide a conductivity gradient even in the layer 410 due to height differences from the irradiation process.

Positioner 430 can be configured to translate first frontside layer 410 relative to reticle stage 200. For example, positioner 430 can translate first frontside layer 410 along a vertical direction (e.g., Z-axis) towards burls 208 of electrostatic clamp 204. In some embodiments, positioner 430 can be a six-axis translation stage (e.g., X, Y, Z, yaw, pitch, roll) for six degrees of freedom. For example, positioner 430 can be configured to contact RTC reticle 400 (e.g., first frontside layer 410) with reticle stage 200 in a first surface area, retract RTC reticle 400 from the first area, translate RTC reticle 400 to a second surface area of reticle stage 200, and contact RTC reticle (e.g., first frontside layer 410) with reticle stage 200 in the second surface area. In some embodiments, positioner 430 can include one or more linear motors (e.g., servomotors). In some embodiments, positioner 430 can be positioned at backside 404 of RTC reticle 400. For example, as shown in FIGS. 4 and 5, substrate 406 can be disposed atop positioner 430. In some embodiments, positioner 430 can be an exchange device for loading one or more reticles (e.g., RTC reticle 400) onto electrostatic clamp 204.

### Exemplary Process Cycle

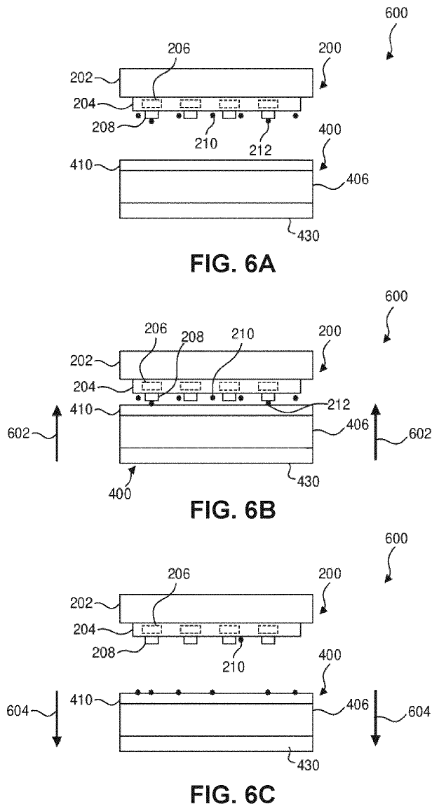

FIGS. 6A-6C illustrate process cycle 600 to remove contaminants (e.g., first particle 210, second particle 212, etc.) from reticle stage 200 to RTC reticle 400, according to various exemplary embodiments. FIG. 6A is a schematic cross-sectional illustration of reticle stage 200 and RTC reticle 400 in an initial step. FIG. 6B is a schematic cross-sectional illustration of reticle stage 200 and RTC reticle 400 in a contact step. FIG. 6C is a schematic cross-sectional illustration of reticle stage 200 and RTC reticle 400 in a retract step.

As shown in FIG. 6A, RTC reticle 400 can approach burls 208 of electrostatic clamp 204 of reticle stage 200 such that burls 208 oppose first frontside layer 410 (e.g., conductive) in a substantially perpendicular direction in an initial step. For example, positioner 430 can align first frontside layer 410 with burls 208 of electrostatic clamp 204. Contaminants (e.g., first particle 210, second particle 212, etc.) are disposed on an exterior surface of electrostatic clamp 204.

As shown in FIG. 6B, RTC reticle 400 can translate vertically (e.g., +Z-axis) towards reticle stage 200 along contact direction 602 and physically contact burls 208 of electrostatic clamp 204 in a contact step. During the contact step, a voltage difference can be applied between RTC reticle 400 and reticle stage 200 (e.g., by applying voltage to clamp electrodes 206 and/or first frontside layer 410) to generate an electrostatic field between RTC reticle 400 and reticle stage 200. The generated electrostatic field creates an electrostatic force (e.g., Lorentz force) and/or a Van der Waals force on contaminants (e.g., first particle 210, second particle 212, etc.) and causes the contaminants to move from reticle stage 200 to RTC reticle 400. Contaminants (e.g., first particle 210, second particle 212, etc.) contact first frontside layer 410 and remain on frontside 402. Further, any charge accumulated on electrostatic clamp 204 can be dissipated when first frontside layer 410 (e.g., conductive polyimide with radicals) contacts electrostatic clamp 204.

As shown in FIG. 6C. RTC reticle 400 can translate vertically (e.g., −Z-axis) away from reticle stage 200 along retract direction 604 and retract from burls 208 of electrostatic clamp 204 in a retract step. During the retract step, frontside 402 of RTC reticle 400 can retain most if not all of contaminants (e.g., first particle 210, second particle 212, etc.) from electrostatic clamp 204 on first frontside layer 410.

In some embodiments, the contact step shown in FIG. 6B and the retract step shown in FIG. 6C can be repeated (e.g., multiple cycles) to further remove contaminants (e.g., first particle 210, second particle 212, etc.) from electrostatic clamp 204 to RTC reticle 400. In some embodiments, process cycle 600 can include contacting reticle stage 200 with RTC reticle 400 in a first surface area, retracting RTC reticle 400, translating RTC reticle 400 (e.g., via positioner 430), and contacting reticle stage 200 with RTC reticle 400 in a second surface area different from the first surface area.

### Exemplary Alternative RTC Reticle Apparatuses

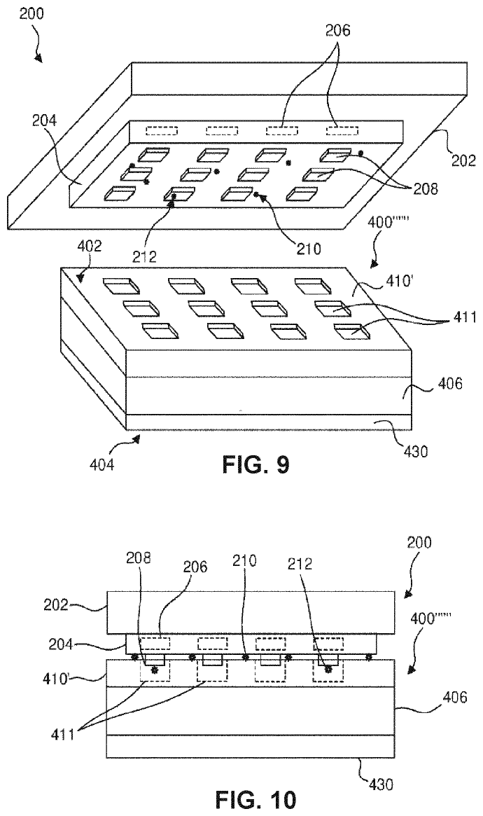

FIGS. 7-14 illustrate RTC reticles 400′, 400″, 400′″, 400″″, 400′″″, 400″″″ according to various exemplary embodiments. FIG. 7 is a schematic perspective illustration of RTC reticle 400′, according to an exemplary embodiment. FIG. 8 is a schematic cross-sectional illustration of RTC reticle 400′ shown in FIG. 7 (along the plane indicated by VIII-VIII in FIG. 7. FIG. 9 is a schematic perspective illustration of reticle stage 200 and RTC reticle 400″″″, according to an exemplary embodiment. FIG. 10 is a schematic cross-sectional illustration of reticle stage 200 and RTC reticle 400″″″ shown in FIG. 9.

FIGS. 7 and 8 illustrate RTC reticle 400′, according to certain embodiments. The embodiments of RTC reticle 400 shown in FIGS. 4 and 5, for example, and the embodiments of RTC reticle 400′ shown in FIGS. 7 and 8 may be similar. Similar reference numbers are used to indicate features of the embodiments of RTC reticle 400 shown in FIGS. 4 and 5 and the similar features of the embodiments of RTC reticle 400′ shown in FIGS. 7 and 8. One difference between the embodiments of RTC reticle 400 shown in FIGS. 4 and 5 and the embodiments of RTC reticle 400′ shown in FIGS. 7 and 8 is that RTC reticle 400′ includes second frontside layer 412 disposed between substrate 406 and first frontside layer 410, rather than just first frontside layer 410 shown in FIGS. 4 and 5. Although RTC reticle 400′ is shown in FIGS. 7 and 8 as a stand-alone apparatus and/or system, the embodiments of this disclosure can be used with other apparatuses and/or systems, such as, but not limited to, lithographic apparatus LA, support structure MT, reticle stage 200, patterning device MA, and/or reticle 300.

As shown in FIGS. 7 and 8, RTC reticle 400′ can include second frontside layer 412. Second frontside layer 412 can be configured to generate an electrostatic field between reticle stage 200 and RTC reticle 400′.

In some embodiments, second frontside layer 412 can be insulating in order to generate an electrostatic field between reticle stage 200 and RTC reticle 400′. For example, second frontside layer 412 can include an insulating polymer, a combination of polymers, polyimide, Viton®, PTFE, Teflon, fluoropolymers, oxides, nitrides, and/or any other insulating material with a stiffness lower than that of first frontside layer 410.

In some embodiments, second frontside layer 412 can be conductive. For example, first frontside layer 410 can include a metal (e.g., Cr, Au, Ti, Cu, Pt, Ag, etc.), a conductive polymer (e.g., conductive polyimide (e.g., by being irradiated to generate radicals therein), Kapton® XC polyimide, Vespel® SP-202 (Dupont), Upilex (UBE Industries), Cirlex (FRALOCK), Norton (Saint Gobain) etc.) and/or some combination thereof.

FIGS. 9 and 10 illustrate RTC reticle 400″″″, according to certain embodiments. The embodiments of RTC reticle 400 shown in FIGS. 4 and 5, for example, and the embodiments of RTC reticle 400″″″ shown in FIGS. 9 and 10 may be similar. Similar reference numbers are used to indicate features of the embodiments of RTC reticle 400 shown in FIGS. 4 and 5 and the similar features of the embodiments of RTC reticle 400″″″ shown in FIGS. 9 and 10. One difference between the embodiments of RTC reticle 400 shown in FIGS. 4 and 5 and the embodiments of RTC reticle 400″″″ shown in FIGS. 13 and 14 is that RTC reticle 400″″″ includes first frontside layer recesses 411 formed in first frontside layer 410′ and configured to receive corresponding burls 208 of electrostatic clamp 204, rather than just first frontside layer 410 shown in FIGS. 4 and 5. Although RTC reticle 400″″″ is shown in FIGS. 9 and 10 as a stand-alone apparatus and/or system, the embodiments of this disclosure can be used with other apparatuses and/or systems, such as, but not limited to, lithographic apparatus LA, support structure MT, reticle stage 200, patterning device MA, and/or reticle 300.

As shown in FIGS. 9 and 10, RTC reticle 400″″″ can include first frontside layer 410′ with first frontside layer recesses 411. First frontside layer 410′ can be configured to generate an electrostatic field between reticle stage 200 and RTC reticle 400″″″. First frontside layer 410′ can be further configured to generate the electrostatic field to remove contaminants (e.g., first particle 210, second particle 212, etc.) on reticle stage 200 (e.g., electrostatic clamp 204). For example, as shown in FIG. 10, first frontside recesses 411 can receive burls 208 and first frontside layer 410′ can contact an area between burls 208 in order to remove contaminants (e.g., first particle 210) on electrostatic clamp 204.

In some embodiments, first frontside layer recesses 411 can be arranged in a pattern (e.g., linear, array, spiral, concentric, etc.) aligned with corresponding burls 208 of electrostatic clamp 204. For example, as shown in FIGS. 9 and 10, first frontside layer recesses 411 can be symmetrically arranged in an array (e.g., 3×4) in first frontside layer 410′. In some embodiments, first frontside layer recesses 411 can be a recess (empty void) within first frontside layer 410′. For example, first frontside layer recesses 411 can include holes, empty cuboids, voids, apertures, notches, and/or any other suitable geometric recess to receive burls 208. In some embodiments, first frontside layer recesses 411 can have a diameter (e.g., holes) or a diagonal (e.g., empty cuboids) of about 0.5 mm to about 3 mm. For example, first frontside layer recesses 411 can have a diameter of about 1 mm.

In some embodiments, first frontside layer 410′ can be insulating in order to generate an electrostatic field between reticle stage 200 and RTC reticle 400″″″ For example, first frontside layer 410′ can include an insulating polymer, a combination of polymers, polyimide, Viton®, PTFE, Teflon, fluoropolymers, oxides, nitrides, and/or any other insulating material. In some embodiments, burls 208 of electrostatic clamp 204 can be placed (positioned) within first frontside layer recesses 411 such that burls 208 do not contact first frontside layer 410′ but an exterior surface of electrostatic clamp 204 surrounding burls 208 does contact first frontside layer 410′ in order to remove contaminants (e.g., first particle 210) disposed between burls 208. For example, as shown in FIG. 10, burls 208 can be disposed in first frontside layer recesses 411 in order to remove first particles 210 between burls 208. In some embodiments, a depth of first frontside layer recesses 411 can be greater than a height of burls 208. For example, as shown in FIG. 10, first frontside layer 410′ can have a thickness such that burls 208, when placed into first frontside layer recesses 411, cannot contact first frontside layer 410′. In some embodiments, first frontside layer 410′ is formed as an irradiated polyimide as described above.

### Exemplary Manufacturing Flow Diagram

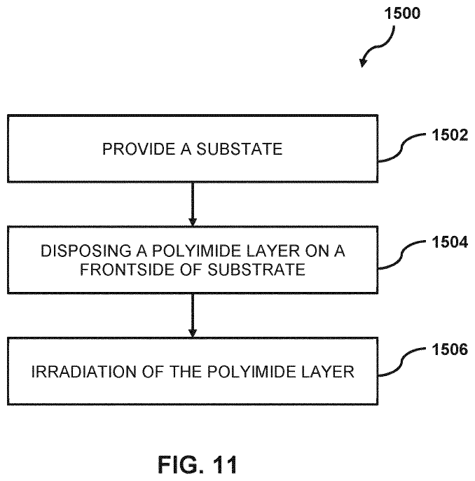

FIG. 11 illustrates manufacturing flow diagram 1500 for manufacturing RTC reticles as described above according to an exemplary embodiment. It is to be appreciated that not all steps in FIG. 11 are needed to perform the disclosure provided herein. Further, some of the steps may be performed simultaneously, sequentially, and/or in a different order than shown in FIG. 11.

Manufacturing flow diagram 1500 shall be described with reference to FIGS. 4, 5, and 7-10. However, manufacturing diagram 1500 is not limited to those example embodiments.

In step 1502, a substrate 406 is provided.

In step 1504, first frontside layer 410 can be deposited on frontside 402 of substrate 406. In some embodiments, first frontside layer 410 can be formed by deposition. For example, first frontside layer 410 can be formed or deposited by any suitable method including chemical vapor deposition (CVD), plasma-enhanced CVD (PECVD), low pressure CVD (LPCVD), atomic layer deposition (ALD), pulsed laser deposition (PLD), electron beam physical vapor deposition (EBPVD), sputtering (e.g., RF, electronic, potential, chemical), ion-beam deposition, spin-on deposition, liquid source misted chemical deposition, and/or other suitable deposition methods. In one embodiment, the layer 410 can also be formed by a coating process, such as spin coating, dip coating, and/or other coating processes.

For example, non-limiting examples of the first frontside polyimide layer 410 material can be Kapton® XC polyimide, Vespel® SP-202, Upilex (UBE Industries), Cirlex (FRALOCK), Norton (Saint Gobain) and/or combinations thereof. Polyimide can be synthesized by a one step or two step process. In the two-step process, the first step is to react a dianhydride and a diamine at ambient conditions in a dipolar aprotic solvent such as N, N-dimethylacetamide (DMAc) or N-methylpyrolidinone (NMP) to achieve poly(amic acid). The second step is the cyclization of the poly(amic acid) to form polyimide. In short, synthesize poly(amic acid) and its cyclization.

In step 1506, the frontside polyimide layer 410 is irradiated with radiation to increase a conductivity of the polyimide layer. The irradiation of the polyimide layer forms radicals in the polyimide layer to increase the conductivity of the polyimide layer.

In one or more embodiments, the irradiating 1506 comprises using one or more of an electron beam, gamma radiation, ultraviolet photons, laser radiation or microwaves.

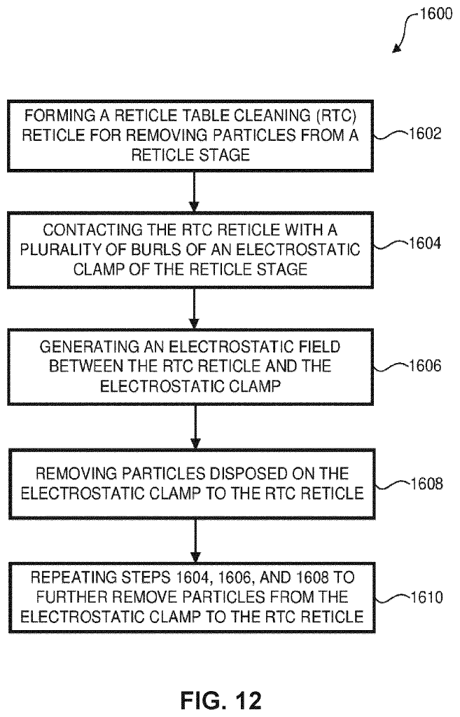

In one or more embodiments, the irradiating to form radicals is conducted either under vacuum or under atmospheric conditions. In the embodiment in which the irradiating is conducted under vacuum conditions, such irradiating can be conducted within the vacuum environment of the lithographic apparatus LA described above, although in another embodiment it can be conducted in a different vacuum area outside the apparatus LA. A vacuum pump or other vacuum system can be used to create the vacuum. In the embodiment where the irradiating is conducted at atmospheric conditions (e.g., approximately at atmospheric pressure=/−5% as a non-limiting example), such irradiating can be conducted in an area or chamber having a supply of inert gas (e.g., Ar, He, Ne, for example) provided thereto. FIG. 12 illustrates cleaning flow diagram 1600 for removing contaminants (e.g., first particle 210, second particle 212, etc.) from reticle stage 200 to RTC reticles 400, 400′, 400″, 400′″, 400″″, 400′″″, 400″″″, according to an exemplary embodiment. It is to be appreciated that not all steps in FIG. 12 are needed to perform the disclosure provided herein. Further, some of the steps may be performed simultaneously. sequentially, and/or in a different order than shown in FIG. 12. Cleaning flow diagram 1600 shall be described with reference to FIGS. 4-10. However, cleaning flow diagram 1600 is not limited to those example embodiments.

In step 1602, as shown in the example of FIGS. 4-10, RTC reticle 400,400′, 400″, 400′″, 400″″, 400′″″, 400″″″ can be formed for removing contaminants (e.g., first particle 210, second particle 212, etc.) from reticle stage 200. In some embodiments, as shown in FIG. 11, RTC reticles 400,400′, 400″, 400′″, 400″″, 400′″″, 400″″″ can be formed using manufacturing flow diagram 1500.

In step 1604, as shown in the example of FIG. 6B, RTC reticle 400,400′, 400″, 400′″, 400″″, 400′″″, 400″″″ can contact burls 208 of electrostatic clamp 204 of reticle stage 200. In some embodiments, RTC reticles 400, 400′, 400″, 400′″, 400″″, 400′″″, 400″″″ can physically contact burls 208 of electrostatic clamp 204 of reticle stage 200 such that burls 208 oppose first frontside layer 410 (e.g., conductive) in a substantially perpendicular direction. For example, positioner 430 can align first frontside layer 410 with burls 208 of electrostatic clamp 204. In some embodiments, RTC reticles 400, 400′, 400″, 400′″, 400″″, 400′″″, 400″″″ can physically contact burls 208 of electrostatic clamp 204 of reticle stage 200 such that burls 208 oppose second frontside layer 412′, 412″ (e.g., conductive) in a substantially perpendicular direction. For example, positioner 430 can align second frontside layer 412′, 412″ with burls 208 of electrostatic clamp 204.

In step 1606, as shown in the example of FIG. 6B, one or more electrostatic fields can be generated between RTC reticle 400, 400′, 400″, 400′″, 400″″, 400′″″, 400′″″ and electrostatic clamp 204 of reticle stage 200. In some embodiments, a voltage difference can be applied between RTC reticle 400 and reticle stage 200 (e.g., by applying voltage to clamp electrodes 206 and/or first frontside layer 410) to generate an electrostatic field between RTC reticle 400 and reticle stage 200. In some embodiments, a first electrostatic field can be generated between first frontside layer 410 and electrostatic clamp 204 (e.g., between burls 208), and a second electrostatic field can be generated between second frontside layer 412′, 412″ and electrostatic clamp 204 (e.g., at burls 208).

In step 1608, as shown in the example of FIG. 6C, contaminants (e.g., first particle 210, second particle 212, etc.) disposed on electrostatic clamp 204 can be removed from reticle stage 200 to RTC reticle 400,400′, 400″, 400′″, 400″″, 400′″″, 400″″″. In some embodiments, the one or more generated electrostatic fields create an electrostatic force(s) (e.g., Lorentz force) and/or a Van der Waals force(s) on contaminants (e.g., first particle 210, second particle 212, etc.) and causes the contaminants to move from reticle stage 200 to RTC reticle 400. Contaminants (e.g., first particle 210, second particle 212, etc.) contact first frontside layer 410 (e.g., conductive) and/or second frontside layer 412′, 412″ (e.g., conductive) and remain on frontside 402. Further, any charge accumulated on electrostatic clamp 204 can be dissipated when first frontside layer 410 (e.g., conductive) contacts electrostatic clamp 204.

In step 1610, as shown in the example of FIGS. 6A-6C, steps 1604, 1606, and 1608 can be repeated (e.g., multiple cycles) to further remove contaminants (e.g., first particle 210, second particle 212, etc.) from electrostatic clamp 204 to RTC reticle 400, 400′, 400″, 400′″, 400″″, 400′″″, 400″″″.

In some embodiments, step 1604 can include contacting burls 208 with first frontside layer 410 in order to dissipate charge accumulated on electrostatic clamp 204. In some embodiments, step 1604 can include contacting burls 208 with second frontside layer 412′, 412″ in order to remove contaminants (e.g., first particle 210, second particle 212, etc.) on electrostatic clamp 204. In some embodiments, step 1604 can include contacting burls 208 with first frontside layer 410, 410′ in order to remove contaminants (e.g., first particle 210, second particle 212, etc.) on electrostatic clamp 204. For example, as shown in FIGS. 13 and 14, burls 208 can be disposed in first frontside layer recesses 411 such that contaminants (e.g., first particle 210) between burls 208 can be removed.

In some embodiments, step 1606 can include generating an electrostatic field between second frontside layer 412′, 412″ and electrostatic clamp 204. For example, a voltage can be applied to first frontside layer 410 in a bottom surface of grooves 414,414′ that is electrically coupled to second frontside layer 412′, 412″ atop first frontside layer 410 within grooves 414,414′.

Various embodiments of the present systems and methods are disclosed in the subsequent list of numbered clauses:
1. A cleaning apparatus for cleaning a reticle stage of a lithographic apparatus, the apparatus comprising:
   a substrate having a frontside and a backside opposite the frontside; and
   a polyimide layer disposed on the frontside of the substrate and configured to contact the reticle stage to remove particles on the reticle stage,
   the polyimide layer having radicals therein to provide the polyimide layer with a conductivity for dissipating charge on the reticle stage.
2. The apparatus of clause 1, wherein the radicals are formed at least in part from a broken C—N bond in an imide group of the polyimide layer.
3. The apparatus of any of the above clauses, wherein the radicals are formed at least in part from a broken C—O bond of a polyimide proton.
4. The apparatus of any of the preceding clauses, wherein the polyimide layer has stiffness lower than that of the substrate, and a thickness no greater than 8 microns in order to generate an electrostatic field between the polyimide layer and the reticle stage.
5. The apparatus of any of the preceding clauses, further comprising a chromium nitride layer disposed between the polyimide layer and the substrate; and
   a positioner coupled to the backside of the substrate and configured to translate the polyimide layer relative to the reticle stage.
6. A lithographic apparatus comprising:
   an illumination system configured to illuminate a patterning device;
   a projection system configured to project an image of the patterning device onto a patterning substrate;
   a reticle stage configured to support the patterning device and comprising a chuck and an electrostatic clamp comprising a plurality of burls; and
   a cleaning apparatus for cleaning the reticle stage, the apparatus comprising:
   a substrate having a frontside and a backside opposite the frontside; and
   a polyimide layer disposed on the frontside of the substrate and configured to contact the reticle stage to dissipate charge on the reticle stage and to remove particles on the reticle stage,
   the polyimide layer having radicals therein to provide the polyimide layer with a conductivity for dissipating charge on the reticle stage.
7. The lithographic apparatus of clause 6, wherein the polyimide layer has a stiffness lower than a stiffness of the substrate.
8. A method of forming a reticle stage cleaning apparatus for removing particles on a reticle stage in a lithographic apparatus, the method comprising:
   providing a substrate having a frontside and a backside opposite the frontside;
   disposing a polyimide layer on the frontside of the substrate; and
   irradiating the polyimide layer with radiation to increase a conductivity of the polyimide layer.
9. A method according to clause 8, wherein the irradiation of the polyimide layer forms radicals in the polyimide layer to increase the conductivity of the polyimide layer.
10. A method according to clauses 8 or 9, wherein the irradiating comprises using one or more of an electron beam, gamma radiation, ultraviolet photons, laser radiation or microwaves.
11. A method according to any of clauses 8-10, wherein polyimide of the polyimide layer is formed by reacting a dianhydride and a diamine at ambient conditions in a dipolar aprotic solvent to achieve poly(amic acid), and subsequent cyclization of the poly(amic acid) to form the polyimide.
12. A method according to any of clauses 8-11, wherein the irradiating is conducted in vacuum conditions.
13. A method according to any of clauses 8-11, where in the irradiating is conducted at atmospheric conditions in the presence of supplied inert gas.
14. A method according to any of clauses 8-12, wherein the irradiating is conducted within a lithographic apparatus.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track unit (a tool that typically applies a layer of resist to a substrate and develops the exposed resist), a metrology unit and/or an inspection unit. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments in the context of optical lithography, it will be appreciated that embodiments may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some embodiments, the substrate itself may be patterned and materials added on top of it may also be patterned or may remain without patterning.

The following examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

Although specific reference may be made in this text to the use of the apparatus and/or system in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments have been described above, it will be appreciated that the embodiments may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary embodiments as contemplated by the inventor(s), and thus, are not intended to limit the embodiments and the appended claims in any way.

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the embodiments that others can, by applying knowledge within the skill of the art, readily modify and/or adapt for various applications such specific embodiments, without undue experimentation, without departing from the general concept of the embodiments. Therefore, such adaptations and modifications are intended to be within the meaning and range of equivalents of the disclosed embodiments, based on the teaching and guidance presented herein.

The breadth and scope of the embodiments should not be limited by any of the above-described exemplary embodiments but should be defined only in accordance with the following claims and their equivalents.

1. A cleaning apparatus for cleaning a reticle stage of a lithographic apparatus, the apparatus comprising:
a substrate having a frontside and a backside opposite the frontside; and
a polyimide layer disposed on the frontside of the substrate and configured to contact the reticle stage to remove particles on the reticle stage,
the polyimide layer having radicals therein to provide the polyimide layer with a conductivity for dissipating charge on the reticle stage.

2. The apparatus of claim 1, wherein the radicals are formed at least in part from a broken C—N bond in an imide group of the polyimide layer.

3. The apparatus of claim 1, wherein the radicals are formed at least in part from a broken C—O bond of a polyimide proton.

4. The apparatus of claim 1, wherein the polyimide layer has stiffness lower than that of the substrate, and a thickness no greater than 8 microns in order to generate an electrostatic field between the polyimide layer and the reticle stage.

5. The apparatus of claim 1, further comprising a chromium nitride layer disposed between the polyimide layer and the substrate; and
a positioner coupled to the backside of the substrate and configured to translate the polyimide layer relative to the reticle stage.

6. A lithographic apparatus comprising:
an illumination system configured to illuminate a patterning device;
a projection system configured to project an image of the patterning device onto a patterning substrate;
a reticle stage configured to support the patterning device and comprising a chuck and an electrostatic clamp comprising a plurality of burls; and
a cleaning apparatus for cleaning the reticle stage, the cleaning apparatus comprising:
a substrate having a frontside and a backside opposite the frontside; and
a polyimide layer disposed on the frontside of the substrate and configured to contact the reticle stage to dissipate charge on the reticle stage and to remove particles on the reticle stage, the polyimide layer having radicals therein to provide the polyimide layer with a conductivity for dissipating charge on the reticle stage.

7. The lithographic apparatus of claim 6, wherein the polyimide layer has a stiffness lower than a stiffness of the substrate.

8. A method for removing particles on a reticle stage of a lithographic apparatus, the method comprising:
providing a substrate having a frontside and a backside opposite the frontside, wherein a polyimide layer is disposed on the frontside of the substrate; and
irradiating the polyimide layer with radiation to increase a conductivity of the polyimide layer.

9. The method according to claim 8, wherein the irradiation of the polyimide layer forms radicals in the polyimide layer to increase the conductivity of the polyimide layer.

10. The method according to claim 8, wherein the irradiating comprises using one or more selected from: of an electron beam, gamma radiation, ultraviolet photons, laser radiation or microwaves.

11. The method according to claim 8, wherein polyimide of the polyimide layer is formed by reacting a dianhydride and a diamine at ambient conditions in a dipolar aprotic solvent to achieve poly(amic acid), and subsequent cyclization of the poly(amic acid) to form the polyimide.

12. The method according to claim 8, wherein the irradiating is conducted in vacuum conditions.

13. The method according to claim 8, wherein the irradiating is conducted at atmospheric conditions in the presence of supplied inert gas.

14. The method according to claim 8, wherein the irradiating is conducted within a lithographic apparatus.

15. The method according to claim 8, wherein the polyimide layer has a thickness no greater than 8 microns in order to generate an electrostatic field between the polyimide layer and the reticle stage.

16. The apparatus of claim 1, wherein the polyimide layer has a stiffness lower than a stiffness of the substrate.

17. The lithographic apparatus of claim 6, further comprising a chromium nitride layer disposed between the polyimide layer and the substrate; and
a positioner coupled to the backside of the substrate and configured to translate the polyimide layer relative to the reticle stage.

18. The lithographic apparatus of claim 6, wherein the radicals are formed at least in part from a broken C—N bond in an imide group of the polyimide layer.

19. The lithographic apparatus of claim 6, wherein the radicals are formed at least in part from a broken C—O bond of a polyimide proton.

20. The lithographic apparatus of claim 7, wherein the polyimide layer has a thickness no greater than 8 microns in order to generate an electrostatic field between the polyimide layer and the reticle stage.
